(19) United States
(12) Patent Application Publication
(10) Pub. No.: US 2022/0173734 A1
(43) Pub. Date: Jun. 2, 2022

(54) DRIVE CIRCUIT AND DRIVE SYSTEM

(71) Applicant: NIDEC CORPORATION, Kyoto (JP)

(72) Inventors: Masaki YOSHINAGA, Kyoto (JP); Taro AMAGAI, Kyoto (JP); Akiko IKEDA, Kyoto (JP); Kengo ARAKI, Kyoto (JP)

(21) Appl. No.: 17/442,622

(22) PCT Filed: Jan. 16, 2020
(86) PCT No.: PCT/JP2020/001295

§ 371 Date: Sep. 24, 2021

(30) Foreign Application Priority Data
Mar. 26, 2019 (JP) 2019-057809

(51) Int. Cl. H03K 17/687; H03K 19/08; H02M 1/08; H03K 17/60; H03K 17/041

(52) U.S. Cl. CPC H03K 17/687; H03K 19/08; H03K 17/04106; H03K 17/60; H02M 1/08

(57) ABSTRACT

Proposed is a drive circuit including: a driving NMOS transistor having a source set to a reference potential and a driving PMOS transistor having a source set to a first potential, the driving NMOS transistor and the driving PMOS transistor having a mutually common drain connected to a load; a first bipolar transistor configured to control on/off of the driving PMOS transistor; a first switching element that causes conduction or non-conduction between a gate and the source of the driving NMOS transistor; and a second switching element that causes conduction or non-conduction between a gate and the source of the driving PMOS transistor.

### CROSS-REFERENCE TO RELATED APPLICATIONS

This is the U.S. national stage of application No. PCT/JP2020/001295, filed on Jan. 16, 2020, and priority under 35 U.S.C. § 119(a) and 35 U.S.C. § 365(b) is claimed from Japanese Patent Application No. 2019-057809, filed on Mar. 26, 2019.

### FIELD OF THE INVENTION

The present invention relates to a drive circuit and a drive system.

### BACKGROUND

Conventionally, as an inverter device for driving a motor, there is known a device provided with a dedicated IC that generates a signal for a switching element controlling a voltage applied to a motor based on a command from a microcontroller.

In a case where a dedicated IC is provided in a drive circuit that drives a load, such as a motor, a degree of freedom in design is high, and thus, it is advantageous in terms of characteristics, for example, power consumption, responsiveness, an energy loss, and the like as compared with a case where the dedicated IC is not provided, but it is disadvantageous in terms of cost.

### SUMMARY

An exemplary embodiment of the present invention relates to a drive circuit including: a driving NMOS transistor having a source set to a reference potential and a driving PMOS transistor having a source set to a first potential, the driving NMOS transistor and the driving PMOS transistor having a mutually common drain connected to a load; a first bipolar transistor configured to control on/off of the driving PMOS transistor; a first resistor having one end connected to a collector of the first bipolar transistor and another end set to the first potential; a first switching element that causes conduction or non-conduction between a gate and the source of the driving NMOS transistor; and a second switching element that causes conduction or non-conduction between a gate and the source of the driving PMOS transistor. The gate of the driving NMOS transistor is connected to a first input terminal to which a first pulse signal varying between the reference potential and a second potential, lower than the first potential, is input. The first switching element causes conduction between the gate and the source of the driving NMOS transistor when the first pulse signal is at the reference potential, and causes non-conduction between the gate and the source of the driving NMOS transistor when the first pulse signal is at the second potential. A base of the first bipolar transistor is connected to a second input terminal to which a second pulse signal varying between the reference potential and the second potential is input. The second switching element causes conduction between the gate and the source of the driving PMOS transistor when the second pulse signal is at the reference potential, and causes non-conduction between the gate and the source of the driving PMOS transistor when the second pulse signal is at the second potential.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a diagram showing a system configuration of a motor drive system according to a first embodiment;

FIG. 2 is a circuit diagram of a reference circuit;

FIG. 3 is a circuit diagram of a drive circuit according to the first embodiment;

FIG. 4 is a timing chart showing an operation of the drive circuit according to the first embodiment;

FIG. 5 is a circuit diagram of a drive circuit according to a second embodiment;

FIG. 6 is a timing chart showing an operation of the drive circuit according to the second embodiment;

FIG. 7 is a circuit diagram of a drive circuit according to a third embodiment;

FIG. 8 is a timing chart showing an operation of the drive circuit according to the third embodiment;

FIG. 9 is a circuit diagram of a drive circuit according to the fourth embodiment;

FIG. 10 is a circuit diagram of a drive circuit according to a fifth embodiment;

FIG. 11 is a circuit diagram of a drive circuit according to a sixth embodiment;

FIG. 12 is a circuit diagram of a drive circuit according to a seventh embodiment; and

FIG. 13 is a timing chart showing an operation of the drive circuit according to the seventh embodiment.

### DETAILED DESCRIPTION

Hereinafter, a motor drive system which is an embodiment of a drive system of the present invention will be described.

Hereinafter, an embodiment of a motor drive system of the present invention will be described with reference to the drawings.

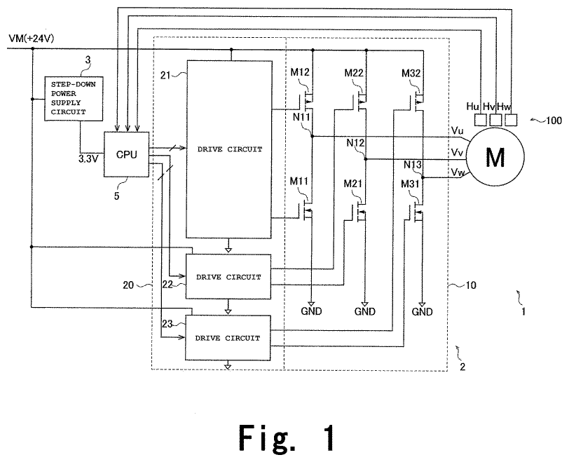

FIG. 1 is a diagram showing a system configuration of a motor drive system 1 according to the embodiment. The motor drive system 1 includes an inverter device 2, a step-down power supply circuit 3, a central processing unit (CPU) 5, and a three-phase AC motor M. The CPU 5 is an example of a microcontroller.

The inverter device 2 includes a three-phase voltage generation unit 10 and a drive circuit group 20, generates three-phase AC power, and supplies the three-phase AC power to a three-phase AC motor M. The three-phase AC motor M is provided with a Hall sensor 100 for each phase for detecting a position of a rotor.

In the following description, a voltage of a node or a terminal in a circuit means a potential with a ground potential GND (hereinafter, referred to as a “GND potential”) as a reference. For example, the highest potential in the inverter device 2 is a power supply potential VM (+24 V), but the GND potential may be regarded as 0 V, and accordingly, is also referred to as “power supply voltage VM” as appropriate.

The step-down power supply circuit 3 reduces the power supply voltage VM (+24 V) to a predetermined voltage (+3.3 V in the present embodiment) required for the operation of the CPU 5, and supplies the power supply voltage VM to the CPU 5.

The CPU 5 supplies a pulse signal having an amplitude of 3.3 V to each of drive circuits 21 to 23 of the drive circuit group 20. Each drive circuit converts the pulse signal from the CPU 5 to a signal level at which a MOS transistor in the three-phase voltage generation unit 10 can operate.

In FIG. 1, the drive circuits 21 to 23 respectively correspond to nodes N11 to N13 and correspond to output terminals of a drive circuit to be described below.

Hereinafter, the configuration of the inverter device 2 will be described in detail.

As shown in FIG. 1, the three-phase voltage generation unit 10 of the inverter device 2 includes NMOS transistors M11, M21, and M31 as low-side switches and PMOS transistors M12, M22, and M32 as high-side switches. Since the three-phase AC motor M may operate at 100% duty in some cases, the three-phase voltage generation unit 10 uses the high-side switch as the PMOS transistor.

In the present embodiment, the PMOS transistor M12 and the NMOS transistor M11 are provided for a U phase of three-phase AC power supplied to the three-phase AC motor M. The PMOS transistor M12 and the NMOS transistor M11 perform the switching operation to generate a U-phase voltage Vu which is a U-phase output voltage.

Similarly, the PMOS transistor M22 and the NMOS transistor M21 are provided for a V phase of the three-phase AC power supplied to the three-phase AC motor M. The PMOS transistor M22 and the NMOS transistor M21 perform the switching operation to generate a V-phase voltage Vv which is a V-phase output voltage. The PMOS transistor M32 and the NMOS transistor M31 are provided for a W phase of the three-phase AC power supplied to the three-phase AC motor M. The PMOS transistor M32 and the NMOS transistor M31 perform the switching operation to generate a W-phase voltage Vw which is a W-phase output voltage.

Each of the NMOS transistors M11, M21, and M31 has a source set to the ground potential GND. Each of the PMOS transistors M12, M22, M32 has a source connected to the power supply voltage VM of the inverter device 2.

A common drain (the node N11) of the NMOS transistor M11 and the PMOS transistor M12 of the U phase is connected to one end of a U-phase winding (not shown) of the three-phase AC motor M. Similarly, a common drain (the node N12) of the NMOS transistor M21 and the PMOS transistor M22 of the V phase is connected to one end of a V-phase winding (not shown) of the three-phase AC motor M, and a common drain (the node N13) of the NMOS transistor M31 and the PMOS transistor M32 of the W phase is connected to one end of a W-phase winding (not shown) of the three-phase AC motor M.

The CPU 5 determines a duty ratio of the pulse signal supplied to the drive circuit 21 to 23 of the drive circuit group 20 based on signals Hu, Hv, and Hw indicating detection values of the respective phases of the Hall sensor 100 that detects the position of the rotor of the three-phase AC motor M. Note that the signals Hu, Hv, and Hw are sine wave signals each having a phase difference of 120 degrees in this order. The CPU 5 supplies the pulse signal having the determined duty ratio to each drive circuit. The amplitude of the pulse signal to be supplied to each drive circuit is 3.3 V, which is the same as an operating voltage of the CPU 5.

Each drive circuit of the drive circuit group 20 converts a level of the pulse signal from the CPU 5 having the amplitude of 3.3 V, and inputs the converted pulse signal to a gate of the PMOS transistor and a gate of the MMOS transistor of the three-phase voltage generation unit 10. The drive circuit 21 inputs the level-converted pulse signal to each gate of the NMOS transistor M11 and PMOS transistor M12 of the U phase. The drive circuit 22 inputs the level-converted pulse signal to each gate of the NMOS transistor M21 and PMOS transistor M22 of the V phase. The drive circuit 23 inputs the level-converted pulse signal to each gate of the NMOS transistor M31 and PMOS transistor M32 of the W phase.

The operations of the NMOS transistors M11, M21, and M31 as the low-side switches and the PMOS transistors M12, M22, and M32 as the high-side switches are controlled by the pulse signals whose levels have been converted by the drive circuits 21, 22, and 23, respectively.

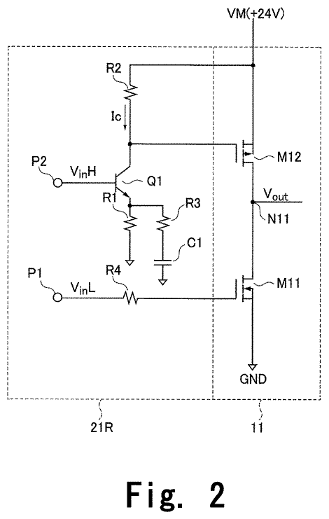

Hereinafter, a configuration of the drive circuit group 20 will be described in more detail with reference to FIG. 2. FIG. 2 shows a circuit configuration of a drive circuit including the drive circuit 21 and the U-phase NMOS transistor M11 and PMOS transistor M12 corresponding to the drive circuit 21 in the three-phase voltage generation unit 10.

A drive circuit including the drive circuit 22 and the corresponding V-phase NMOS transistor M21 and PMOS transistor M22, and a drive circuit including the drive circuit 23 and the corresponding W-phase NMOS transistor M31 and PMOS transistor M32 is similar to that in the case of the U phase. Therefore, only the case of the U phase will be described hereinafter, and redundant descriptions for the V phase and the W phase will be omitted.

Before describing the drive circuit 21 according to the present embodiment, a reference circuit 21R, which is a drive circuit for reference, will be described with reference to FIG. 2 for the purpose of comparison with the drive circuit 21. Note that a U-phase generation unit 11 of the three-phase voltage generation unit 10 is shown in FIG. 2.

In the U-phase generation unit 11, the common drain of the NMOS transistor M11 (an example of a driving NMOS transistor) and the PMOS transistor M12 (an example of a driving PMOS transistor) is connected to the three-phase AC motor M as a load. The source of the NMOS transistor M11 is set to the ground potential GND, and the source of the PMOS transistor M12 is set to the power supply potential VM.

The reference circuit 21R processes a signal such that the potentials of the gates of the NMOS transistor M11 and the PMOS transistor M12 vary between the ground potential GND and the power supply voltage VM (+24 V; an example of a first potential) based on potentials of an input terminal P1 and an input terminal P2, which vary between the ground potential GND (an example of a reference potential) and 3.3 V (an example of a second potential).

From the CPU 5, mutually complementary pulse signals VinL and VinH varying between the ground potential GND and 3.3 V are input to the input terminal P1 and the input terminal P2, respectively.

As shown in FIG. 2, the reference circuit 21R includes an NPN transistor Q1, resistors R1 to R4, and a capacitor C1.

The NPN transistor Q1 (an example of a first bipolar transistor) is provided to control on/off of the PMOS transistor M12. In the reference circuit 21R, the bipolar transistor (that is, the NPN transistor Q1) is provided on the high side in consideration of a gate withstand voltage of the MOS transistor.

One end of the resistor R4 is connected to the input terminal P1, and the other end of the resistor R4 is connected to the gate of the NMOS transistor M11. One end of the resistor R2 (an example of a first resistor) is connected to a collector of the NPN transistor Q1, and the other end is set to the power supply voltage VM.

The resistor R1 has one end connected to an emitter of the NPN transistor Q1, and the other end set to the ground potential GND. The resistor R3 and the capacitor C1 are connected in parallel to the resistor R1.

The reference circuit 21R operates as follows.

On the low side, the pulse signal VinL varying between the ground potential GND and 3.3 V from the CPU 5 is directly input to the gate of the NMOS transistor M11 via the resistor R4. When the pulse signal VinL is at 3.3 V, the NMOS transistor M11 is turned on. When the pulse signal VinL is at the ground potential GND, the NMOS transistor M11 is turned off.

On the high side, the NPN transistor Q1 is turned on when the pulse signal VinH is at 3.3 V, and the PMOS transistor M12 is turned on due to a voltage drop caused by a collector current Ic flowing through the resistor R2. When the pulse signal VinH is at the ground potential GND, the NPN transistor Q1 is turned off, the collector current Ic does not flow through the resistor R2, and the PMOS transistor M12 is also turned off. Note that the collector current Ic is transiently increased by the capacitor C1 which is a speed-up capacitor in order to speed up the turn-on of the PMOS transistor M12.

The reference circuit 21R has the following problems.

(Problem 1) The current consumption is great when the PMOS transistor M12 is turned on.

Since the NPN transistor Q1 is turned on during a period in which the PMOS transistor M12 is constantly turned on, the collector current Ic always flows, so that the current consumption does not become zero.

(Problem 2) An operation is slow when the PMOS transistor M12 is turned off.

The time when the PMOS transistor M12 is turned off is determined by a gate parasitic capacitance of the PMOS transistor M12 and a time constant according to the resistor R2. Therefore, it is necessary to decrease the resistor R2 in order to speed up the time when the PMOS transistor M12 is turned off. On the other hand, a voltage drop caused by the resistor R2 needs to be equal to or higher than a threshold voltage of a voltage Vas between the gate and the source when the PMOS transistor M12 is turned on, the collector current Ic needs to be increased by the amount of the decrease of the resistor R2. That is, there is a trade-off relationship between the time when the PMOS transistor M12 is turned off and the current consumption.

(Problem 3) An on-resistance is high when the NMOS transistor M11 is turned on.

The on-resistance is high since the voltage of 3.3 V supplied from the CPU 5 is directly input to the NMOS transistor M11 in the reference circuit 21R. In order to lower the on-resistance, it is necessary to increase the voltage of the pulse signal VinL when the NMOS transistor M11 is turned on to be higher than 3.3 V.

(Problem 4) A margin of self-turn-on of the NMOS transistor M11 and the PMOS transistor M12 is small.

A switching loss of the PMOS transistor M12 is reduced by transiently increasing the collector current Ic by the capacitor C1 to speed up the turn-on of the PMOS transistor M12. However, when an output voltage Vout increases at a high speed, a gate potential of the NMOS transistor M11 also increases at a high speed via a capacitance between the gate and the drain of the NMOS transistor M11, and the NMOS transistor M11 is self-turned on if the voltage between the gate and the source exceeds the threshold voltage.

Conversely, the switching loss of the NMOS transistor M11 is reduced by decreasing the gate resistance R4 of the NMOS transistor M11 and speeding up the turn-on of the NMOS transistor M11. However, the output voltage Vout drops at a high speed, the gate potential of the PMOS transistor M12 drops at a high speed via the capacitance between the gate and the drain of the PMOS transistor M12, and the PMOS transistor M12 is self-turn-on if the voltage between the source and the gate exceeds the threshold voltage.

In view of the above-described problems of the reference circuit 21R, the drive circuit 21 according to the present embodiment is a circuit that copes with Problems 1, 2, and 4 among the above-described problems.

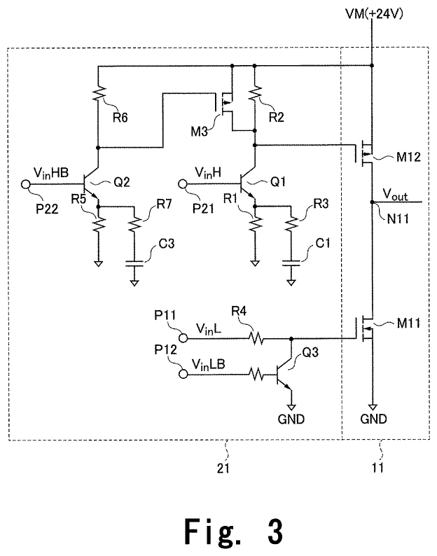

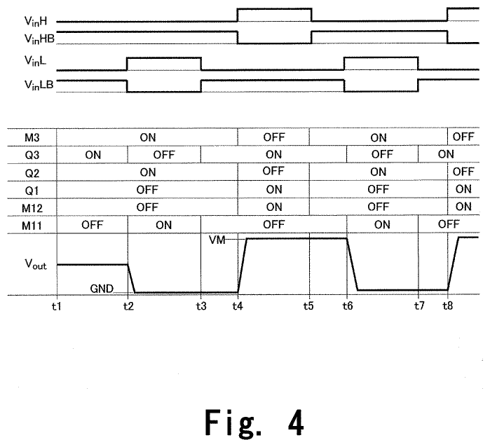

Hereinafter, the drive circuit 21 according to the present embodiment will be described with reference to FIGS. 3 and 4. FIG. 3 is a circuit diagram of the drive circuit 21 according to the present embodiment. FIG. 4 is a timing chart showing an operation of the drive circuit 21 according to the present embodiment.

As can be seen by comparing FIG. 3 with FIG. 2, the drive circuit 21 according to the present embodiment is different from the reference circuit 21R in that NPN transistors Q2 and Q3, a PMOS transistor M3, and a resistor R6 (an example of a second resistor) are added.

The drive circuit 21 processes a signal such that the potentials of the gates of the NMOS transistor M11 and the PMOS transistor M12 vary between the ground potential GND and the power supply voltage VM (+24 V; an example of the first potential) based on potentials of input terminals P11, P12, P21, and P22, which vary between the ground potential GND (an example of the reference potential) and 3.3 V (an example of the second potential).

From the CPU 5, mutually complementary pulse signals VinL and VinLB varying between the ground potential GND and 3.3 V are input to the input terminals P11 and P12, respectively. The pulse signal VinLB is a signal inverted from the pulse signal VinL (an example of a first pulse signal). The input terminal P11 is an example of a first input terminal.

From the CPU 5, mutually complementary pulse signals VinH and VinHB varying between the ground potential GND and 3.3 V are input to the input terminals P21 and P22, respectively. The pulse signal VinHB is a signal inverted from the pulse signal VinH (an example of a second pulse signal). The input terminal P21 is an example of a second input terminal.

The pulse signal VinL is input to the gate of the NMOS transistor M11 from the input terminal P11 via the resistor R4.

The NPN transistor Q3 (an example of a first switching element and a second bipolar transistor) is an element that causes conduction or non-conduction between the gate and the source of the NMOS transistor M11. The pulse signal VinLB is input from the input terminal P12 to a base of the NPN transistor Q3. An emitter of the NPN transistor Q3 is set to the ground potential GND, and a collector of the NPN transistor Q3 is connected to the gate of the NMOS transistor M11. The NPN transistor Q3 causes conduction between the gate and the source of the NMOS transistor M11 when the pulse signal VinL is at the ground potential GND, and causes non-conduction between the gate and the source of the NMOS transistor M11 when the pulse signal VinL is at 3.3 V.

The PMOS transistor M3 (an example of a second switching element) is an element that causes conduction or non-conduction between the gate and the source of the PMOS transistor M12.

A source and a drain of the PMOS transistor M3 are connected to both ends of the resistor R2, respectively. The PMOS transistor M3 causes conduction between the gate and the source of the PMOS transistor M12 when the pulse signal VinH is at the ground potential GND, and causes non-conduction between the gate and the source of the PMOS transistor M12 when the pulse signal VinH is at 3.3 V. This conduction/non-conduction control is performed by the NPN transistor Q2.

The pulse signal VinH is input from the input terminal P21 to a base of the NPN transistor Q1, and the pulse signal VinHB is input from the input terminal P22 to a base of the NPN transistor Q2.

The resistor R5 has one end connected to an emitter of the NPN transistor Q2, and the other end set to the ground potential GND. The resistor R7 and the capacitor C3 are connected in parallel to the resistor R5. The capacitor C3 functions as a speed-up capacitor that transiently increases a collector current of the NPN transistor Q2.

The collector of the NPN transistor Q2 is connected to a gate of the PMOS transistor M3 and is connected to the power supply voltage VM via the load resistor R6.

Next, the operation of the drive circuit 21 will be described with reference to FIG. 4.

FIG. 4 shows waveforms of the pulse signals VinH, VinHB, VinL, and VinLB, operating states (ON or OFF) of the transistors Q1 to Q3, M11, M12, and M3, and waveforms of the output voltage Vout with a lapse of time.

In an initial period from time t1 to time t2 in the timing chart of FIG. 4, the pulse signal VinL is at the ground potential GND (hereinafter, referred to as an “L level”), the pulse signal VinLB is at 3.3 V (hereinafter, referred to as an “H level”), the pulse signal VinH is at the L level, and the pulse signal VinHB is at the H level. Therefore, on the lower side, the NMOS transistor M11 is turned off since the NPN transistor Q3 is turned on. On the high side, the NPN transistor Q2 is turned on, and the PMOS transistor M3 is turned on by a voltage drop of the collector current in the resistor R6. When the PMOS transistor M3 is turned on, the voltage between the gate and the source of the PMOS transistor M12 does not exceed the threshold, and the PMOS transistor M12 is turned off.

That is, since both the NMOS transistor M11 and the PMOS transistor M12 are turned off, the output voltage Vout is in a floating state (indefinite).

At time t2, the pulse signal VinL becomes the H level, and the pulse signal VinLB becomes the L level. Therefore, the NPN transistor Q3 is turned off, and the NMOS transistor M11 is turned on. As a result, the output voltage Vout drops from the floating state to the ground potential GND.

Note that the PMOS transistor M12 remains off since there is no change in the pulse signals VinH and VinHB on the high side.

At time t3, the pulse signal VinL becomes the L level, and the pulse signal VinLB becomes the H level. Therefore, the NPN transistor Q3 is turned on, and the NMOS transistor M11 is turned off. On the other hand, the PMOS transistor M12 remains off since there is no change in the pulse signals VinH and VinHB on the high side. Accordingly, the output voltage Vout remains at the ground potential GND.

At time t4, the pulse signal VinH becomes the H level, and the pulse signal VinHB becomes the L level. Therefore, the NPN transistor Q1 is turned on, and the NPN transistor Q2 is turned off. When the NPN transistor Q2 is turned off, the collector current does not flow through the load resistor R6, and thus, the PMOS transistor M3 is turned off. When the collector current of the NPN transistor Q1 flows through the load resistor R2, the voltage between the gate and the source of the PMOS transistor M12 exceeds the threshold by the voltage drop in the resistor R2, and the PMOS transistor M12 is turned on.

On the other hand, the NMOS transistor M11 remains off since there is no change in the pulse signals VinL and VinLB on the low side.

Accordingly, the PMOS transistor M12 is turned on, and the NMOS transistor M11 is turned off, and thus, the output voltage Vout increases to the power supply voltage VM.

At time t5, levels of the respective pulse signals become the same states as those at time t1. That is, since both the NMOS transistor M11 and the PMOS transistor M12 are turned off, the output voltage Vout remains at the power supply voltage VM.

At time t6 and the subsequent times, the same operation as that at time t2 and the subsequent times is repeated.

Since the PMOS transistor M3 is provided on the high side, the drive circuit 21 according to the present embodiment can quickly reduce the voltage between the gate and the source of the PMOS transistor M12 when the PMOS transistor M12 is turned off. That is, even in a case where the resistors R1 and R2 have large values, the operation when the PMOS transistor M12 is turned off can be speeded up. That is, even in a case where the resistors R1 and R2 are increased in order to reduce power consumption, it is possible to maintain the high-speed operation when the PMOS transistor M12 is turned off. Accordingly, the drive circuit 21 according to the present embodiment can solve Problem 1 and Problem 2 of the reference circuit 21R.

In addition, since the NPN transistor Q3 is provided on the low side, the voltage between the gate and the source of the NMOS transistor M11 can be quickly reduced when the NMOS transistor M11 is turned off, and thus, the operation when the NMOS transistor M11 is turned off can also be speeded up.

Since the NPN transistor Q3 is provided on the low side and the PMOS transistor M3 is provided on the high side, the drive circuit 21 according to the present embodiment can increase the margin of self-turn-on of the NMOS transistor M11 and the PMOS transistor M12.

That is, when the output voltage Vout increases at a high speed (for example, time t4 in FIG. 4), the NPN transistor Q3 is turned on, and an impedance between the gate and the source of the NMOS transistor M11 is low in the drive circuit 21 according to the present embodiment. Thus, the gate potential of the NMOS transistor M11 is less likely to increase via the capacitance between the gate and the drain. Therefore, the margin of self-turn-on of the NMOS transistor M11 increases.

Conversely, when the output voltage Vout drops at a high speed (for example, time t6 in FIG. 4), the PMOS transistor M3 is turned on, and an impedance between the gate and the source of the PMOS transistor M12 is low in the drive circuit 21 according to the present embodiment. Thus, the gate potential of the PMOS transistor M12 is less likely to drop via the capacitance between the gate and the drain. Therefore, the margin of self-turn-on of the PMOS transistor M12 increases.

Accordingly, Problem 4 of the reference circuit 21R can be solved.

As described above, the drive circuits 21 to 23 convert the levels of the pulse signals directly supplied from the CPU 5 to drive the NMOS transistors M11, M21, and M31 and the PMOS transistors M12, M22, and M32 of the three-phase voltage generation unit 10 in the motor drive system 1 according to the present embodiment. Therefore, it is possible to improve the performance without using a dedicated IC when the three-phase AC motor M is driven by switching. Furthermore, there is an advantage that Problems 1, 2, and 4 of the reference circuit 21R can be solved by using the drive circuit according to the present embodiment.

A motor drive system according to each of second and subsequent embodiments is different from that of the first embodiment only in terms of a configuration of a drive circuit, and thus, a difference in the drive circuit will be described.

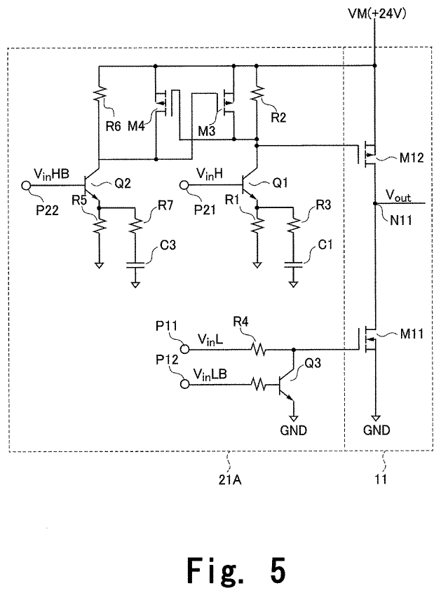

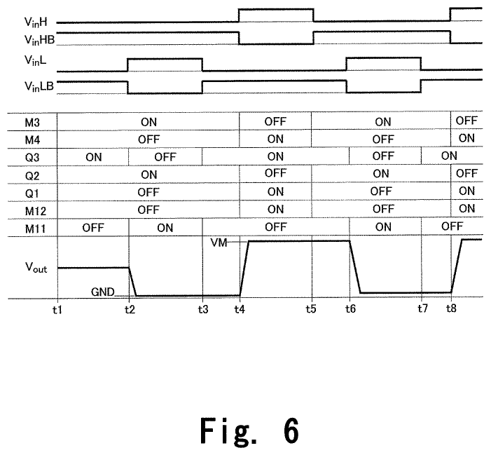

Hereinafter, a drive circuit 21A according to the second embodiment will be described with reference to FIGS. 5 and 6. FIG. 5 is a circuit diagram of the drive circuit 21A according to the second embodiment. FIG. 6 is a timing chart showing an operation of the drive circuit 21A according to the second embodiment.

As can be seen by comparing FIG. 5 with FIG. 3, the drive circuit 21A according to the present embodiment is different from the drive circuit 21 according to the first embodiment in that a PMOS transistor M4 (an example of a second PMOS transistor) is added. A source of the PMOS transistor M4 is set to the power supply voltage VM in common with a source of the PMOS transistor M3. A drain of the PMOS transistor M4 is connected to the gate of the PMOS transistor M3. A gate of the PMOS transistor M4 is connected to the gate of the PMOS transistor M12.

In the timing chart of FIG. 6, an operating state (ON or OFF) of the PMOS transistor M4 is added to the timing chart of FIG. 4. As shown in FIG. 6, the PMOS transistor M4 operates so as to be turned off when the PMOS transistor M3 is turned on, and to be turned on when the PMOS transistor M3 is turned off. The PMOS transistor M4 is provided to turn off the PMOS transistor M3 at a higher speed.

In FIG. 6, the NPN transistor Q2 is turned on and the PMOS transistor M3 is turned on at time t1 as described above, and thus, the PMOS transistor M12 is turned off. Since the PMOS transistor M3 is turned on, a voltage between the gate and the source of the PMOS transistor M4 does not exceed a threshold, and the PMOS transistor M4 is turned off.

From time t1 to time t4, the PMOS transistor M4 remains off since there is no change in the pulse signals VinH and VinHB.

At time t4, the pulse signal VinH becomes the H level, and the pulse signal VinHB becomes the L level. Then, the NPN transistor Q1 is turned on, and the NPN transistor Q2 is turned off. When the NPN transistor Q1 is turned on, the collector current flows through the resistor R2, and the PMOS transistor M4 is turned on by a voltage drop of the resistor R2, whereby the PMOS transistor M3 is quickly turned off. That is, the PMOS transistor M4 operates to turn off the PMOS transistor M3 at a high speed. When the PMOS transistor M3 is turned off at a high speed, the PMOS transistor M12 is turned on at a high speed.

At time t5, the pulse signal VinH becomes the L level, and the pulse signal VinHB becomes the H level. Then, the NPN transistor Q1 is turned off, and the NPN transistor Q2 is turned on. No current flows through the resistor R2, and the PMOS transistor M12 is turned off. The collector current of the NPN transistor Q2 flows through the resistor R6, thereby turning on the PMOS transistor M3 and turning off the PMOS transistor M4.

As described above, since the PMOS transistor M4 is provided, the PMOS transistor M12 can be turned on and off more quickly than the drive circuit according to the first embodiment.

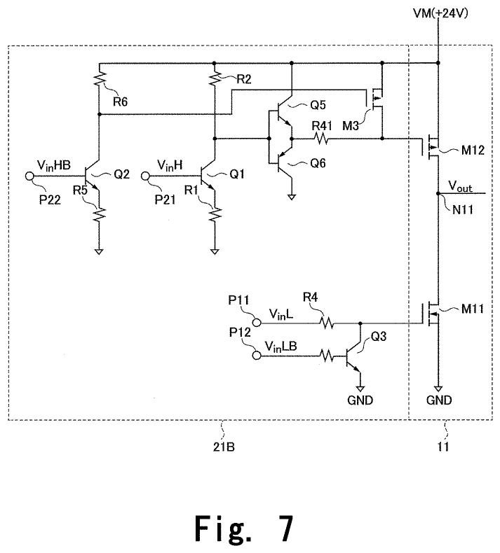

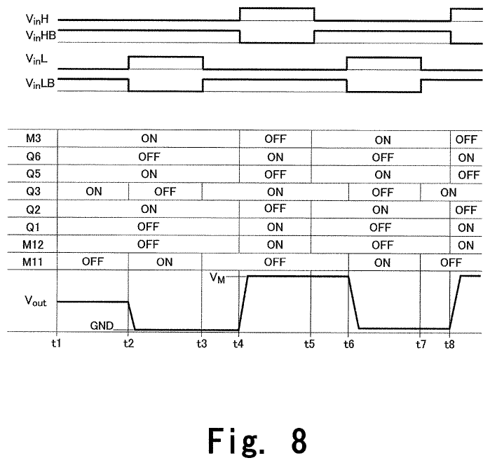

Hereinafter, a drive circuit 21B according to a third embodiment will be described with reference to FIGS. 7 and 8. FIG. 7 is a circuit diagram of the drive circuit 21B according to the third embodiment. FIG. 8 is a timing chart showing an operation of the drive circuit 21B according to the third embodiment.

As can be seen by comparing FIG. 7 with FIG. 3, the drive circuit 21B according to the present embodiment is different from the drive circuit 21 according to the first embodiment in that a push-pull circuit including an NPN transistor Q5 and a PNP transistor Q6 is provided between the collector of the NPN transistor Q1 and the gate of the PMOS transistor M12. In addition, the resistors R3 and R7 and the capacitors C1 and C7 are eliminated in the drive circuit 21B as compared with the drive circuit 21.

More specifically, bases of the NPN transistor Q5 and the PNP transistor Q6 are connected to the collector of the NPN transistor Q1. Emitters of the NPN transistor Q5 and the PNP transistor Q6 are connected to the gate of the PMOS transistor M12 via a resistor R41. A collector of the NPN transistor Q5 is set to the power supply voltage VM, and a collector of the PNP transistor Q6 is set to the ground potential GND.

At time t1 in FIG. 8, the NPN transistor Q1 is turned off, and the NPN transistor Q2 is turned on. Since the PMOS transistor M3 is turned on, the PMOS transistor M12 is turned off. At this time, the NPN transistor Q5 is turned on by a current flowing from the resistor R2 to the base of the NPN transistor Q5, and the PNP transistor Q6 is turned off.

At time t4, the NPN transistor Q1 is turned on, and the NPN transistor Q2 is turned off. At this time, a base current flows in a direction from the base of the PNP transistor Q6 toward the collector of the NPN transistor Q1, the gate potential of the PMOS transistor M12 decreases, and the PMOS transistor M12 is turned on.

At time t5, the NPN transistor Q1 is turned off, and the NPN transistor Q2 is turned on. In this case, the NPN transistor Q5 is turned on and the PNP transistor Q6 is turned off as in a period from time t1 to time t2. During a period from time t5 to time t6, both the NMOS transistor M11 and the PMOS transistor M12 are turned off, and thus, the output voltage Vout maintains the power supply voltage VM as in the first embodiment.

According to the drive circuit 21B of the present embodiment, it is possible to speed up the operation when the PMOS transistor M12 is turned off while achieving low power consumption by increasing the resistors R2 and R6, which is similar to the drive circuit 21 of the first embodiment.

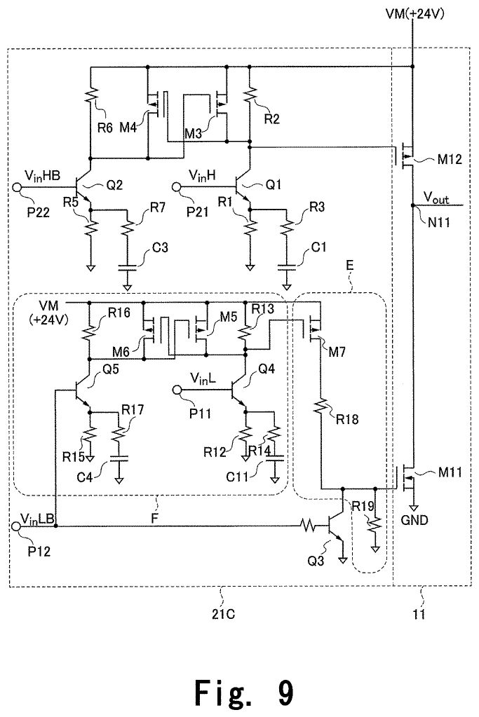

Hereinafter, a drive circuit 21C according to a fourth embodiment will be described with reference to FIG. 9. FIG. 9 is a circuit diagram of the drive circuit 21C according to the fourth embodiment.

As can be seen by comparing FIG. 9 with FIG. 5, the drive circuit 21C according to the present embodiment is different from the drive circuit 21A according to the second embodiment in that a part E and a part F are provided on the low side.

The part E includes a PMOS transistor M7 (an example of a third switching element) and resistors R18 and R19.

The part F has the same circuit configuration as that on the high side with respect to the PMOS transistor M7 of the part E. That is, resistors R12, R13, R14, R15, R16, and R17, capacitors C11 and C4, the NPN transistors Q4 and Q5, and PMOS transistors M5 and M6 of the part F respectively correspond to the resistors R1, R2, R3, R5, R6, and R7, the capacitors C1 and C3, the NPN transistors Q1 and Q2, and the PMOS transistors M3 and M4 on the high side.

In the part E, a source of the PMOS transistor M7 is set to the power supply voltage VM, and a gate of the PMOS transistor M7 is connected to a collector of the NPN transistor Q4. The resistors R18 and R19 are connected in series between a drain of the PMOS transistor M7 and the ground potential GND, and an intermediate node between the resistor R18 and the resistor R19 is connected to a gate of the NMOS transistor M11. The PMOS transistor M7 is an example of the third switching element provided between the gate of the NMOS transistor M11 and a node of the power supply voltage VM.

In the drive circuit 21C according to the present embodiment, the part E and the part F on the low side are provided to reduce the on-resistance when the NMOS transistor M11 is turned on.

The NMOS transistor M11 is turned on when the pulse signal VinL is at the H level and the pulse signal VinLB is at the L level, which is similar to the other embodiments. That is, when the pulse signal VinL is at the H level and the pulse signal VinLB is at the L level, the NPN transistors Q3 and Q5 are turned off, and the NPN transistor Q4 is turned on. At this time, the PMOS transistor M7 is turned on by a voltage drop in the resistor R13 of a collector current of the NPN transistor Q4, and a gate potential of the NMOS transistor M11 becomes an intermediate potential between the ground potential GND and the power supply voltage VM. That is, when the pulse signal VinL is at the H level, the PMOS transistor M7 as the switching element becomes conductive, and the gate of the NMOS transistor M11 is set to the intermediate potential between the ground potential GND and the power supply voltage VM.

Since the gate of the NMOS transistor M11 is connected to the intermediate node between the resistors R18 and R19, the intermediate potential is a value obtained by dividing the ground potential GND and the power supply voltage VM by the resistors R18 and R19. For example, in a case where values of the resistors R18 and R19 are equal, a voltage between the gate and the source when the NMOS transistor M11 is turned on becomes VM/2 (=12 V), which is a value higher than the H level (3.3 V) of a pulse signal from the CPU 5, so that the on-resistance of the NMOS transistor M11 can be reduced.

On the other hand, when the pulse signal VinL is at the L level and the pulse signal VinLB is at the H level, the NPN transistors Q3 and Q5 are turned on, and the NPN transistor Q4 is turned off. At this time, the PMOS transistor M5 is turned on, and thus, the PMOS transistor M7 is turned off. That is, when the pulse signal VinL is at the ground potential GND, the PMOS transistor M7 as the switching element becomes non-conductive. The gate potential of the NMOS transistor M11 decreases so that the NMOS transistor M11 is turned off.

As described above, the on-resistance of the NMOS transistor M11 can be reduced since the voltage between the gate and the source when the NMOS transistor M11 is turned on can be increased according to the drive circuit 21C of the present embodiment. That is, Problem 3 of the reference circuit 21R can be solved.

Note that the circuit configuration of FIG. 9 is merely an example, and is not intended to require all the elements.

For example, the PMOS transistor M4 is provided on the high side in the circuit configuration of FIG. 9, but the PMOS transistor M4 is not necessarily provided similarly to the drive circuit 21 (see FIG. 3) according to the first embodiment.

In addition, at least the resistor R13, the resistor R12, and the NPN transistor Q4 are required in the part F on the lower side, and the other elements are not necessarily required.

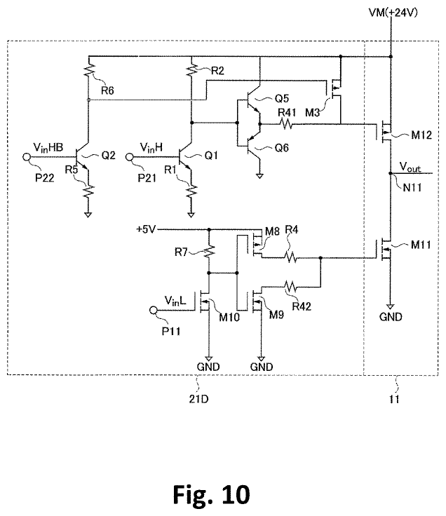

Hereinafter, a drive circuit 21D according to a fifth embodiment will be described with reference to FIG. 10. FIG. 10 is a circuit diagram of the drive circuit 21D according to the fifth embodiment.

As can be seen by comparing FIG. 10 with FIG. 7, the drive circuit 21D according to the present embodiment is different from the drive circuit 21B according to the third embodiment in terms of a low-side circuit configuration. The present embodiment is characterized by the low side, and it is possible to adopt the circuit configuration presented in any of the other embodiments on the high side. Therefore, a high-side circuit configuration shown in FIG. 10 is merely an example.

The drive circuit 21D according to the present embodiment shows a circuit configuration example in a case where, for example, a 5V-power supply can be used. The 5V-power supply may be generated by, for example, the step-down power supply circuit 3 (see FIG. 1).

As shown in FIG. 10, a low-side circuit of the drive circuit 21D includes a CMOS inverter including an NMOS transistor M10, a PMOS transistor M8, and an NMOS transistor M9, and resistors R7, R4, and R42.

The pulse signal VinL is input to a gate of the NMOS transistor M10. A level of the pulse signal VinL is shifted by the NMOS transistor M10 and the resistor R7 and input to the CMOS inverter. An output of the CMOS inverter is input to the gate of the NMOS transistor M11 via the resistors R4 and R42.

For example, when the pulse signal VinL is at the H level, the NMOS transistor M10 is turned on, the PMOS transistor M8 is turned on, and 5 V is input to the gate of the NMOS transistor M11 via the resistor R4.

On the other hand, when the pulse signal VinL is at the L level, the NMOS transistor M10 is turned off, and the NMOS transistor M9 is turned on. At this time, a charge is extracted from the gate of the NMOS transistor M11 via the resistor R42, a potential of the gate decreases, and the NMOS transistor M11 is turned off.

According to the drive circuit 21D of the present embodiment, 5 V is input to the gate when the NMOS transistor M11 is turned on, and thus, the voltage between the gate and the source of the NMOS transistor M11 can be made higher than that in the case where 3.3 V is input from the CPU 5. Therefore, the on-resistance of the NMOS transistor M11 can be reduced.

In addition, there is an advantage that an on-characteristic and an off-characteristic of the NMOS transistor M11 can be set to desired characteristics since the resistors R4 and R42 are provided. For example, the impedance of the gate when the NMOS transistor M11 is turned off can be reduced by reducing the resistor R42, and the margin of self-turn-on can be increased.

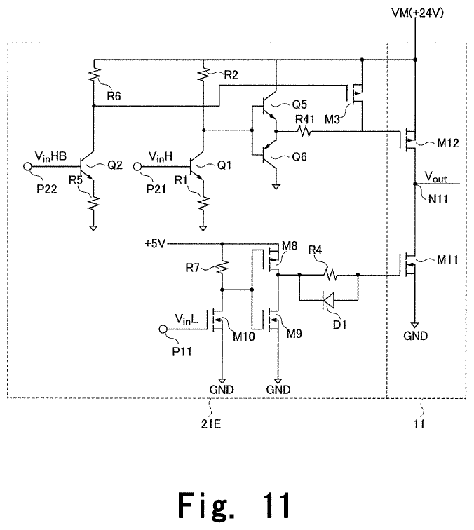

Hereinafter, a drive circuit 21E according to a sixth embodiment will be described with reference to FIG. 11. FIG. 11 is a circuit diagram of the drive circuit 21E according to the sixth embodiment.

The drive circuit 21E according to the present embodiment of FIG. 11 is different from the drive circuit 21D according to the fifth embodiment (FIG. 10) in that a diode D1 is provided in parallel with the resistor R4, instead of the resistor R42.

In the drive circuit 21E according to the present embodiment, when the NMOS transistor M11 is turned off, a charge in a gate capacitance of the NMOS transistor M11 is extracted via the diode D1 to reduce the gate potential of the NMOS transistor M11.

In the above-described reference circuit 21R, when the turn-on of the PMOS transistor M12 is speeded up, the output voltage Vout increases at a high speed. Thus, the gate potential of the NMOS transistor M11 also increases at a high speed via the capacitance between the gate and the drain of the NMOS transistor M11, and the NMOS transistor M11 is self-turned on if the voltage between the gate and the source exceeds the threshold voltage.

On the other hand, in the drive circuit 21E according to the present embodiment, the voltage between the gate and the source of the NMOS transistor M11 is clamped to about 0.7 V by the diode D1, and thus, the voltage does not exceed the threshold voltage, and the self-turn-on does not occur.

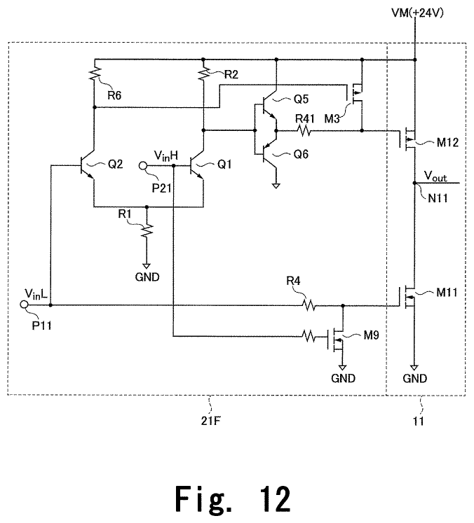

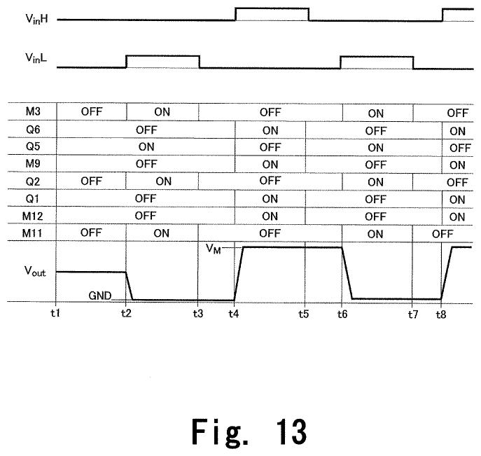

Hereinafter, a drive circuit 21F according to a seventh embodiment will be described with reference to FIGS. 12 and 13. FIG. 12 is a circuit diagram of the drive circuit 21F according to the seventh embodiment. FIG. 13 is a timing chart showing an operation of the drive circuit 21F according to the seventh embodiment.

The drive circuit 21F according to the present embodiment is a modification of the drive circuit 21B (see FIG. 7) according to the third embodiment. As shown in FIG. 12, the drive circuit 21F is different from the drive circuit 21B in terms of the following points.
(i) The NMOS transistor M9 is provided on the low side, instead of the NPN transistor Q3.
(ii) The common resistor R1 is provided between the emitters of the NPN transistors Q1 and Q2 and the ground potential GND.
(iii) The input terminals P11 and P22 are made common to receive the input of the pulse signal VinL.
(iv) The input terminals P12 and P21 are made common to receive the input of the pulse signal VinH.

In the drive circuit 21F according to the present embodiment, the low-side NMOS transistor M9 and the high-side PMOS transistor M3 are elements configured to prevent the self-turn-on.

For example, when the NMOS transistor M11 is turned on at time t2 and the output voltage Vout decreases to the ground potential GND, the PMOS transistor M3 is turned on. Therefore, the impedance between the gate and the source of the PMOS transistor M12 decreases, and thus, the self-turn-on of the PMOS transistor M12 can be prevented.

For example, when the PMOS transistor M12 is turned on and the output voltage Vout rises from the ground potential GND to the power supply voltage VM at time t4, the NMOS transistor M9 is turned on. Therefore, the impedance between the gate and the source of the NMOS transistor M11 decreases, and thus, the self-turn-on of the NMOS transistor M11 can be prevented.

As described above, the embodiments of the drive circuit and the drive system according to the present invention have been described in detail. However, a scope of the present invention is not limited to the above embodiments. In addition, the above-described embodiments can be variously improved or changed within the scope not departing from a gist of the present invention. The technical matters described in each of the plurality of embodiments can be appropriately combined. For example, it is possible to combine a high-side circuit configuration of a drive circuit of a specific embodiment with a low-side circuit configuration of a drive circuit of another embodiment.

For example, the case where the on/off control of each driving MOS transistor of the three-phase voltage generation unit 10 is performed by 120-degree energization based on position information of a Hall sensor has been described in the above-described embodiments, but the invention is not limited thereto. As an on/off control method of each driving MOS transistor, another energization control method such as 180-degree energization may be applied.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

1. A drive circuit comprising:
a driving NMOS transistor having a source set to a reference potential and a driving PMOS transistor having a source set to a first potential, the driving NMOS transistor and the driving PMOS transistor having a mutually common drain connected to a load;
a first bipolar transistor configured to control on/off of the driving PMOS transistor;
a first resistor having one end connected to a collector of the first bipolar transistor and another end set to the first potential;
a first switching element that causes conduction or non-conduction between a gate and the source of the driving NMOS transistor; and
a second switching element that causes conduction or non-conduction between a gate and the source of the driving PMOS transistor,
wherein
the gate of the driving NMOS transistor is connected to a first input terminal to which a first pulse signal varying between the reference potential and a second potential, lower than the first potential, is input,
the first switching element causes conduction between the gate and the source of the driving NMOS transistor when the first pulse signal is at the reference potential, and causes non-conduction between the gate and the source of the driving NMOS transistor when the first pulse signal is at the second potential,
a base of the first bipolar transistor is connected to a second input terminal to which a second pulse signal varying between the reference potential and the second potential is input, and
the second switching element causes conduction between the gate and the source of the driving PMOS transistor when the second pulse signal is at the reference potential, and causes non-conduction between the gate and the source of the driving PMOS transistor when the second pulse signal is at the second potential.

2. The drive circuit according to claim 1, further comprising:
a second bipolar transistor having a base to which an inverted signal of the second pulse signal is input, a collector connected to a gate of a PMOS transistor, and an emitter connected to the reference potential; and
a second resistor having one end connected to the collector of the second bipolar transistor and another end set to the first potential,
wherein the second switching element is the PMOS transistor having a source set to the first potential and a drain connected to the gate of the driving PMOS transistor.

3. The drive circuit according to claim 2, further comprising
a second PMOS transistor having a source set to the first potential in common with the source of the PMOS transistor, a drain connected to the gate of the PMOS transistor, and a gate connected to the gate of the driving PMOS transistor.

4. The drive circuit according to claim 1, further comprising
a push-pull circuit including an NPN transistor and a PNP transistor,
wherein
bases of the NPN transistor and the PNP transistor are connected to the collector of the first bipolar transistor,
emitters of the NPN transistor and the PNP transistor are connected to the gate of the driving PMOS transistor, and
a collector of the NPN transistor is set to the first potential, and a collector of the PNP transistor is set to the reference potential.

5. The drive circuit according to claim 1, further comprising
a third switching element provided between the gate of the driving NMOS transistor and a node of the first potential,
wherein
the third switching element becomes conductive to set the gate of the driving NMOS transistor to an intermediate potential between the reference potential and the first potential when the first pulse signal is at the second potential, and
the third switching element becomes non-conductive when the first pulse signal is at the reference potential.

6. A drive system comprising:
the drive circuit according to claim 1; and
a microcontroller,
wherein potentials of the first input terminal and the second input terminal are set by the microcontroller.
